(19) United States
(12) Patent Application Publication
(10) Pub. No.: US 2014/0084345 A1
(43) Pub. Date: Mar. 27, 2014

(54) COMPOUND SEMICONDUCTOR DEVICE AND METHOD OF MANUFACTURING THE SAME

(71) Applicants: FUJITSU SEMICONDUCTOR LIMITED, Yokohama-shi (JP); FUJITSU LIMITED, Kawasaki-shi (JP)

(72) Inventors: Toshihiro Ohki, Hadano (JP); YUUICHI SATOU, AIZUWAKAMATU (JP)

(73) Assignees: FUJITSU SEMICONDUCTOR LIMITED, Yokohama-shi (JP); FUJITSU LIMITED, Kawasaki-shi (JP)

(21) Appl. No.: 14/030,172

(22) Filed: Sep. 18, 2013

(30) Foreign Application Priority Data
Sep. 27, 2012 (JP) 2012-214846

(51) Int. Cl. H01L 29/778; H01L 21/28

(52) U.S. Cl. CPC H01L 29/778; H01L 21/28
USPC 257/194; 438/602

(57) ABSTRACT

A compound semiconductor device includes: a compound semiconductor stacked structure; a source electrode and a drain electrode formed separately from each other above the compound semiconductor stacked structure; a gate electrode formed between the source electrode and the drain electrode above the compound semiconductor stacked structure; and a passivation film formed above the compound semiconductor stacked structure and made of an insulating material containing Al, in which the passivation film is in a non-contact state with the compound semiconductor stacked structure under the source electrode and the drain electrode.

### CROSS-REFERENCE TO RELATED APPLICATION

This application is based upon and claims the benefit of priority of the prior Japanese Patent Application No. 2012-214846, filed on Sep. 27, 2012, the entire contents of which are incorporated herein by reference.

### FIELD

The embodiments discussed herein are directed to a compound semiconductor device and a method of manufacturing the same.

### BACKGROUND

There is considered application of a nitride semiconductor to a high-withstand-voltage high-output-power semiconductor device, in a manner to utilize characteristics such as high saturation electron velocity and wide band gap. For example, the band gap of GaN as the nitride semiconductor is 3.4 eV, which is larger than the band gap of Si (1.1 eV) and the band gap of GaAs (1.4 eV), and thus GaN has high breakdown electric field intensity. Accordingly, GaN is quite promising as a material of a semiconductor device for power supply that obtains high voltage operation and high output power.

As a semiconductor device using the nitride semiconductor, there have been made a lot of reports on a field effect transistor, particularly a high electron mobility transistor (HEMT). For example, among GaN-based HEMTs (GaN-HEMTs), attention has been paid to an AlGaN/GaN.HEMT using GaN as an electron transit layer and using AlGaN as an electron supply layer. In the AlGaN/GaN.HEMT, a distortion ascribable to a difference in lattice constant between GaN and AlGaN occurs in AlGaN. Due to piezoelectric polarization caused by the distortion and to spontaneous polarization of AlGaN, a high-concentration two-dimensional electron gas (2DEG) is obtained. Accordingly, the AlGaN/GaN.HEMT has been expected as a high efficiency switch element and a high-withstand-voltage electric power device for electric vehicle, or the like.

Patent Document 1: Japanese Laid-open Patent Publication No. 2004-260114

As problems when the semiconductor device using the nitride semiconductor is operated under a high voltage, two of a withstand voltage and a current collapse phenomenon can be cited. The current collapse phenomenon refers to a phenomenon that on-resistance increases by application of a high voltage and is said to occur because electrons are trapped in semiconductor crystals, an interface between a semiconductor and an insulating film, and so on and accordingly the concentration of 2DEG in these regions decreases. This current collapse has been known to greatly rely on a protective film (passivation film) covering the semiconductor, and various film types and film qualities have been studied. Then, we have found that using an AlN film as the passivation film is effective for a reduction in interface state, and it has been clear that particularly AlN formed to a film by an atomic layer deposition method (ALD method) is the most suitable.

There is illustrated an AlGaN/GaN.HEMT using the AlN film for the passivation film in FIG. 1.

In FIG. 1, on a substrate 101 of SiC or the like, an electron transit layer 102 and an electron supply layer 103 are staked, and on the electron supply layer 103, a passivation film 104 is formed. The electron transit layer 102 is i (intentionally.undoped)-GaN or the like, the electron supply layer 103 is n-AlGaN or the like, and the passivation film 104 is AlN. On the passivation film 104, a gate electrode 105 is formed, and on both sides of the gate electrode 105 on the electron supply layer 103 and the passivation film 104, a source electrode 106 and a drain electrode 107 are formed. The source electrode 106 and the drain electrode 107 come into ohmic contact with the electron supply layer 103.

However, it has become clear by our experiment that the AlGaN/GaN.HEMT in FIG. 1 has the following problems.

The passivation film 104 also comes into contact with the source electrode 106 and the drain electrode 107. Therefore, in the process where the source electrode 106 and the drain electrode 107 are brought into ohmic contact with the electron supply layer 103, annealing for obtaining the ohmic contact is performed in a state of the source electrode 106 and the drain electrode 107 being in contact with the passivation film 104. On the other hand, for an electrode material of the source electrode 106 and the drain electrode 107, a structure containing Al typified by Ti/Al (Ti for a lower layer and Al for an upper layer) has been widely used, and with an electrode material containing no Al, a sufficient ohmic characteristic has not been obtained yet.

Normally, the annealing for obtaining the ohmic contact needs a high temperature of 500° C. to 900° C., or so. In the annealing, as illustrated in FIG. 1, the portion where three of the electron supply layer 103, Ti of the source electrode 106 and the drain electrode 107, and the passivation film 104 come into contact with one another simultaneously exists. It has been found that by the high-temperature annealing, in the portion, part of Al of the passivation film 104 reacts with Ti of the source electrode 106 and the drain electrode 107 and contact resistance in the portion changes.

In this case, variations are caused in contact resistance, of the passivation film 104, in a gate width direction and at the time of high-voltage operation, current concentration occurs. Then, it has become clear that device breakdown is caused starting from this current concentration site and a breakdown withstand voltage decreases. Incidentally, it has been also found that the variations are more significantly caused in side surfaces of end portions obtained by dry etching the passivation film. For reducing the current collapse phenomenon, the passivation film made of a material containing Al such as AlN is effective, but has a problem that the sufficient breakdown withstand voltage cannot be obtained.

### SUMMARY

An aspect of a compound semiconductor device includes: a compound semiconductor stacked structure; a pair of first electrodes that are formed separately from each other above the compound semiconductor stacked structure; a second electrode that is formed between the first electrodes above the compound semiconductor stacked structure; and a protective film that is formed above the compound semiconductor stacked structure and made of an insulating material containing aluminum, in which the protective film is in a non-contact state with the compound semiconductor stacked structure under the first electrodes.

An aspect of a method of manufacturing a compound semiconductor device includes: forming a compound semiconductor stacked structure; forming a protective film made of an insulating material containing aluminum above the compound semiconductor stacked structure; forming a pair of first electrodes separated from each other above the compound semiconductor stacked structure; and forming a second electrode between the first electrodes above the compound semiconductor stacked structure, in which the protective film is in a non-contact state with the compound semiconductor stacked structure under the first electrodes.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a schematic cross-sectional view illustrating a conventional AlGaN/GaN.HEMT using an AlN film for a passivation film;

FIG. 2A to FIG. 2C are schematic cross-sectional views illustrating a method of manufacturing an AlGaN/GaN.HEMT according to a first embodiment in order of processes;

FIG. 3A to FIG. 3C are schematic cross-sectional views, subsequent to FIG. 2A to FIG. 2C, illustrating the method of manufacturing the AlGaN/GaN.HEMT according to the first embodiment in order of processes;

FIG. 4 is a characteristic chart presenting an I-V characteristic, of the AlGaN/GaN.HEMT according to the first embodiment, under a typical pinch-off condition, including a comparative example;

FIG. 5A to FIG. 5C are schematic cross-sectional views illustrating main processes of a method of manufacturing an AlGaN/GaN.HEMT according to a modified example of the first embodiment;

FIG. 6A and FIG. 6B are schematic cross-sectional views, subsequent to FIG. 5A to FIG. 5C, illustrating main processes of the method of manufacturing the AlGaN/GaN.HEMT according to the modified example of the first embodiment;

FIG. 7A to FIG. 7C are schematic cross-sectional views illustrating a method of manufacturing an AlGaN/GaN.HEMT according to a second embodiment in order of processes;

FIG. 8A and FIG. 8B are schematic cross-sectional views, subsequent to FIG. 7A to FIG. 7C, illustrating the method of manufacturing the AlGaN/GaN.HEMT according to the second embodiment in order of processes;

FIG. 9A and FIG. 9B are schematic cross-sectional views, subsequent to FIG. 8A and FIG. 8B, illustrating the method of manufacturing the AlGaN/GaN.HEMT according to the second embodiment in order of processes;

FIG. 10A to FIG. 10C are schematic cross-sectional views illustrating main processes of a method of manufacturing an AlGaN/GaN.HEMT according to a modified example of the second embodiment;

FIG. 11A to FIG. 11C are schematic cross-sectional views, subsequent to FIG. 10A to FIG. 10C, illustrating main processes of the method of manufacturing the AlGaN/GaN.HEMT according to the modified example of the second embodiment;

FIG. 12 is a connection diagram illustrating a schematic configuration of a power supply device according to a third embodiment; and

FIG. 13 is a connection diagram illustrating a schematic configuration of a high-frequency amplifier according to a fourth embodiment.

### DESCRIPTION OF EMBODIMENTS

(First Embodiment)

In this embodiment, an AlGaN/GaN.HEMT of a nitride semiconductor is disclosed as a compound semiconductor device. Here, as an example, there is illustrated what is called a MIS-type AlGaN/GaN.HEMT in which a gate electrode is provided on a semiconductor via a gate insulating film.

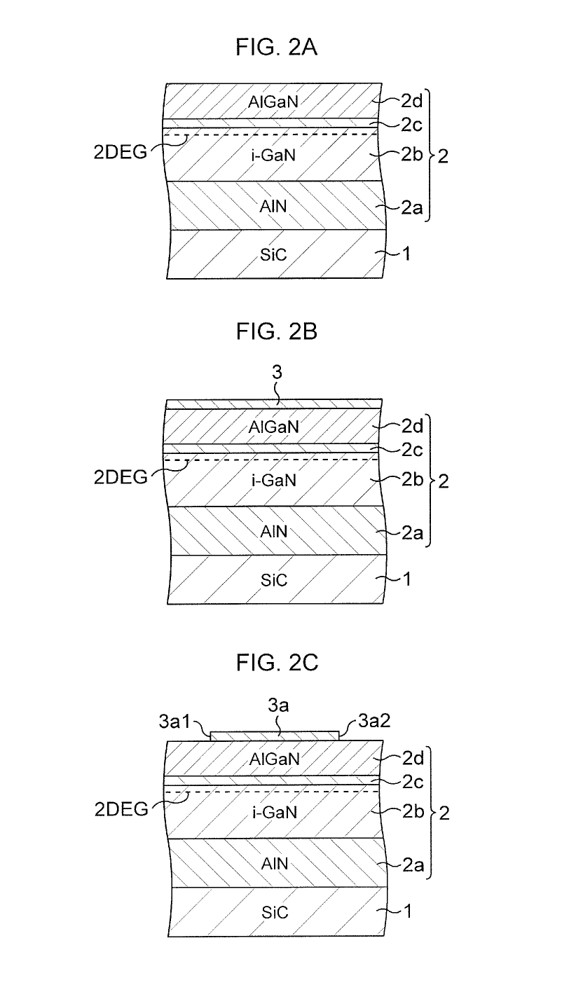

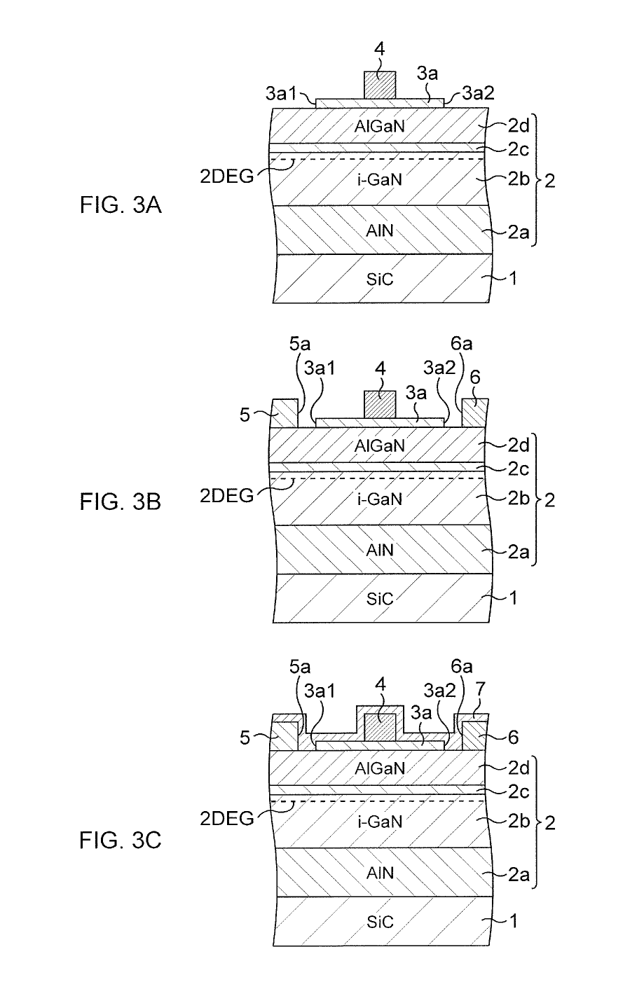

FIG. 2A to FIG. 2C and FIG. 3A to FIG. 3C are schematic cross-sectional views illustrating a method of manufacturing an AlGaN/GaN.HEMT according to a first embodiment in order of processes.

First, as illustrated in FIG. 2A, a compound semiconductor stacked structure 2 is formed on, for example, a semi-insulating SiC substrate 1 as a growth substrate. As the growth substrate, a Si substrate, a sapphire substrate, a GaAs substrate, a GaN substrate, or the like may also be used instead of the SiC substrate. Further, the conductivity of the substrate may be either semi-insulating or conductive.

The compound semiconductor stacked structure 2 includes: a buffer layer 2a; an electron transit layer 2b; an intermediate layer 2c; and an electron supply layer 2d.

In the compound semiconductor stacked structure 2, a two-dimensional electron gas (2DEG) occurs in the vicinity of an interface, of the electron transit layer 2b, with the electron supply layer 2d (to be exact, the intermediate layer 2c). This 2DEG is generated based a difference in lattice constant between the compound semiconductor (here GaN) of the electron transit layer 2b and the compound semiconductor (here AlGaN) of the electron supply layer 2d.

More specifically, on the SiC substrate 1, the following compound semiconductors are each grown by, for example, an MOVPE (Metal Organic Vapor Phase Epitaxy) method. An MBE (Molecular Beam Epitaxy) method or the like may also be used instead of the MOVPE method.

On the SiC substrate 1, AlN is grown to a predetermined thickness, i-GaN is grown to a thickness of 3 μm or so, i-AlGaN is grown to a thickness of 5nm or so, and n-AlGaN is grown to a thickness of 30 nm or so in order. Thereby, the buffer layer 2a, the electron transit layer 2b, the intermediate layer 2c, and the electron supply layer 2d are formed. As the buffer layer 2a, AlGaN may be used instead of AlN, or GaN may also be grown at a low temperature. Further, there is sometimes a case that a thin cap layer made of n-GaN is formed on the electron supply layer 2d.

As a growth condition of AlN, mixed gas of trimethylaluminum (TMAl) gas and ammonia (NH₃) gas is used as a source gas. As a growth condition of GaN, mixed gas of trimethylgallium (TMGa) gas and NH₃ gas is used as a source gas. As a growth condition of AlGaN, mixed gas of TMAl gas, TMGa gas, and NH₃ gas is used as a source gas. According to a compound semiconductor layer to be grown, whether or not to supply the TMAl gas being an Al source and the TMGa gas being a Ga source and flow rates thereof are appropriately set. The flow rate of the NH₃ gas being a common source is set to 100 ccm to 10 LM or so. Further, growth pressure is set to 50 Torr to 300 Torr or so, and growth temperature is set to 1000° C. to 1200° C. or so.

To grow GaN and AlGaN as an n-type, or in this embodiment, to form AlGaN of the electron supply layer 2d, for example, SiH₄ gas containing, for example, Si is added as an n-type impurity to the source gas at a predetermined flow rate, thereby doping AlGaN with Si. The doping concentration of Si is set to 1×10¹⁸/cm³ or so to 1×10²⁰/cm³ or so, for example, set to 5×10¹⁸/cm³ or so.

Subsequently, element isolation structures are formed.

More specifically, for example, argon (Ar) is injected to element isolation regions of the compound semiconductor stacked structure 2. Thereby, the element isolation structures are formed in the compound semiconductor stacked structure 2 and in a surface layer portion of the SiC substrate 1. The element isolation structures demarcate an active region on the compound semiconductor stacked structure 2.

Incidentally, the element isolation may also be performed by using, for example, an STI (Shallow Trench Isolation) method, instead of the above-described injection method. At this time, for example, a chlorine-based etching gas is used for dry etching of the compound semiconductor stacked structure 2.

Subsequently, as illustrated in FIG. 25, an AlN layer 3 is formed.

More specifically, on the compound semiconductor stacked structure 2, an insulating film containing Al, here AlN is deposited to a thickness of 2 nm or so to 200 nm or so, for example, 20 nm or so. For the deposition of AlN, for example, an ALD method is used. Instead of the ALD method, a sputtering method, a plasma CVD method, or the like may also be used. Thereby, the AlN layer 3 is formed. As an insulating material containing Al, for example, AlO (Al₂O₃) may also be used, instead of AlN.

Subsequently, as illustrated in FIG. 2C, the AlN layer 3 is processed to form a passivation film 3a.

More specifically, a resist is applied on the surface of the AlN layer 3. The resist is processed by lithography, and thereby openings exposing opening planned sites of the AlN layer 3 are formed in the resist. Thereby, a resist mask having the openings is formed.

By using this resist mask, the AlN layer 3 is dry etched until a predetermined region of the surface of the electron supply layer 2d is exposed. For an etching gas, for example, a chlorine-based gas is used. The predetermined region of the electron supply layer 2d is a region including source electrode and drain electrode formation planned sites of the surface of the electron supply layer 2d. Incidentally, the dry etching may also be performed in such a manner to slightly shave the AlN layer 3 in a depth direction beyond the surface of the electron supply layer 2d. Thereby, of the residual AlN layer 3, the passivation film 3a exposing the predetermined region of the electron supply layer 2d is formed. Of the passivation film 3a, both end portions formed by the dry etching are set to end portions 3a1 and 3a2.

Subsequently, as illustrated in FIG. 3A, a gate electrode 4 is formed.

More specifically, first, a resist mask for forming the gate electrode is formed. Here, for example, an eaves-structure two-layer resist suitable for a vapor deposition method and a liftoff method is used. This resist is applied on the compound semiconductor stacked structure 2 including the surface of the passivation film 3a and an opening exposing a gate electrode formation planned site of the passivation film 3a is formed. Thereby, the resist mask having the opening is formed.

By using this resist mask, as an electrode material, for example, Ni/Au (Ni for a lower layer and Au for an upper layer) are deposited on the resist mask including the inside of the opening exposing the gate electrode formation planned site of the passivation film 3a by the vapor deposition method, for example. The thickness of Ni is set to 30 nm or so and the thickness of Au is set to 400 nm or so. By the liftoff method, the resist mask and Ni/Au deposited thereon are removed. Thereby, the gate electrode 4 is formed on the passivation film 3a. The gate electrode 4 is formed on the compound semiconductor stacked structure 2 via the passivation film 3a. The portion, of the passivation film 3a, positioned under the gate electrode 4 functions as a gate insulating film.

Thereafter, the resist mask is removed by asking using oxygen plasma or wetting using a chemical solution.

Subsequently, as illustrated in FIG. 3B, a source electrode 5 and a drain electrode 6 are formed.

More specifically, first, a resist mask for forming the source electrode and the drain electrode is formed. Here, for example, an eaves-structure two-layer resist suitable for a vapor deposition method and a liftoff method is used. This resist is applied on the compound semiconductor stacked structure 2 and openings exposing source electrode and drain electrode formation planned sites of the compound semiconductor stacked structure 2 are formed. Thereby, the resist mask having the openings is formed.

By using this resist mask, as an electrode material, for example, Ti/Al (Ti for a lower layer and Al for an upper layer) are deposited on the resist mask including the inside of the openings exposing the respective formation planned sites by the vapor deposition method, for example. The thickness of Ti is set to 20 nm or so and the thickness of Al is set to 200 nm or so. The electrode material may be a metal single layer containing Al, or may also be composed of three or more layers. By the liftoff method, the resist mask and Ti/Al deposited thereon are removed. Thereafter, the SiC substrate 1 is subjected to annealing at a temperature of 400° C. to 1000° C. or so, for example, 550° C. or so in a nitrogen atmosphere, for example, and thereby residual Ti/Al are brought into ohmic contact with the electron supply layer 2d. Thereby, the source electrode 5 and the drain electrode 6 are formed on the compound semiconductor stacked structure 2.

In this embodiment, the passivation film 3a is in a non-contact state with the compound semiconductor stacked structure 2 (electron supply layer 2d) under the source electrode 5 and the drain electrode 6. Concretely, between the source electrode 5 and the drain electrode 4, an end portion 5a of the source electrode 5 is separated from the end portion 3a1 of the passivation film 3a. Similarly, between the drain electrode 6 and the gate electrode 4, an end portion 6a of the drain electrode 6 is separated from the end portion 3a2 of the passivation film 3a.

Since being in a separate non-contact state with the source electrode 5 and the drain electrode 6, the passivation film 3a does not react with the source electrode 5 and the drain electrode 6 at the time of the high-temperature annealing for establishing the ohmic contact of the source electrode 5 and the drain electrode 6. Consequently, distribution of contact resistance, of the passivation film 3a, in a gate width direction becomes uniform and current concentration at the time of high-voltage operation is dispersed, resulting in that a sufficient breakdown withstand voltage can be obtained.

Subsequently, as illustrated in FIG. 3C, a protective insulating film 7 is formed on the whole surface.

More specifically, an insulating film, for example, SiN is deposited to cover the whole surface on the compound semiconductor stacked structure 2 to a thickness of 2 nm or so to 200 nm or so, for example, 20 nm or so, and for the deposition of SiN, a plasma CVD method or a sputtering method is used. As an insulating material, there is sometimes a case that SiON, SiO₂, or the like is used instead of SiN. Thereby, the protective insulating film 7 is formed. The protective insulating film 7 fills a gap between the source electrode 5 and the passivation film 3a and a gap between the drain electrode 6 and the passivation film 3a to function as a protective film.

Thereafter, various processes such as forming an interlayer insulating film, forming wirings connected to the gate electrode 4, the source electrode 5, and the drain electrode 6, forming an upper protective film, and forming a connection electrode exposed on the uppermost surface are undergone. Thereby, the MIS-type AlGaN/GaN.HEMT according to this embodiment is formed.

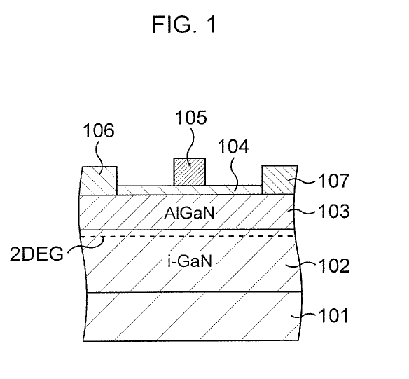

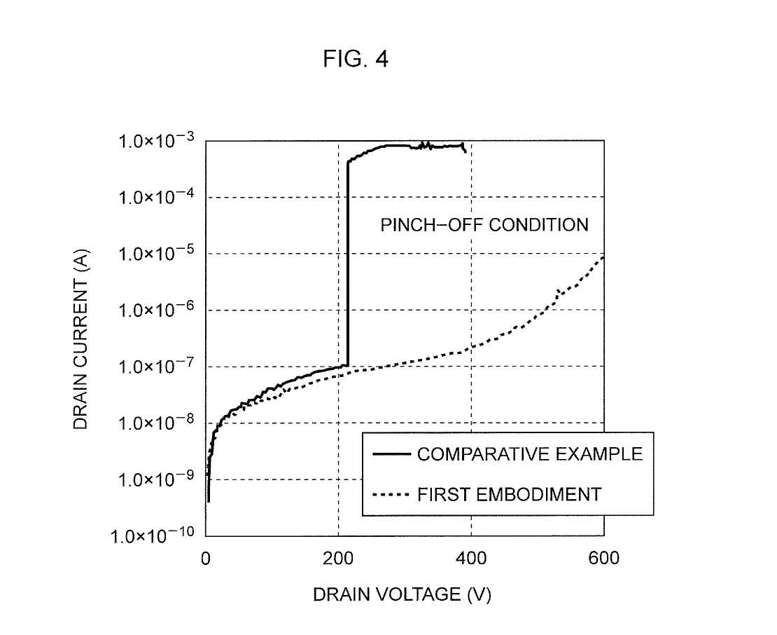

The breakdown withstand voltage of the AlGaN/GaN.HEMT according to this embodiment was examined based on the comparison with an AlGaN/GaN.HEMT illustrated in FIG. 1. A result thereof is presented in FIG. 4. FIG. 4 is a characteristic chart presenting an I-V characteristic, of the AlGaN/GaN.HEMT according to this embodiment, under a typical pinch-off condition, including a comparative example.

In the comparative example, element breakdown is confirmed in the vicinity of 200 V due to electric field concentration. In this embodiment, on the other hand, it became clear that the high breakdown withstand voltage of 600 V or more can be obtained.

As explained above, in this embodiment, the highly reliable high-withstand-voltage AlGaN/GaN.HEMT that reduces the current collapse phenomenon by using the passivation film 3a containing Al and further secures the sufficient breakdown withstand voltage is achieved.

(Modified Example)

Hereinafter, there will be explained a modified example of the first embodiment. In this example, a structure of an AlGaN/GaN.HEMT and a method of manufacturing the same are disclosed as in the first embodiment, but what is called a Schottky-type AlGaN/GaN.HEMT in which a gate electrode comes into Schottky contact with a semiconductor is illustrated as an example. Note that the same constituent members and so on as those of the first embodiment will be denoted by the same reference signs, and a detailed explanation thereof will be omitted.

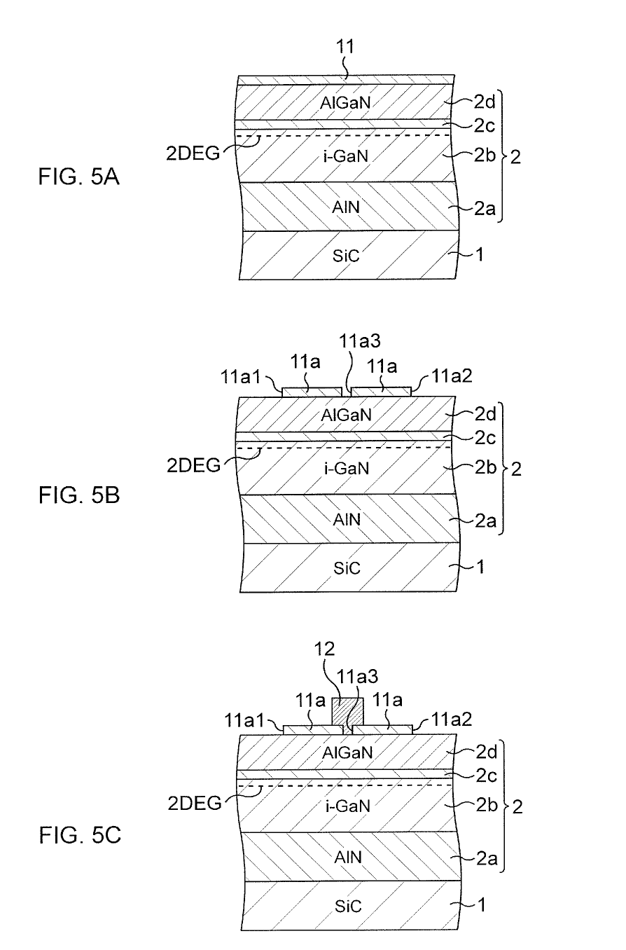

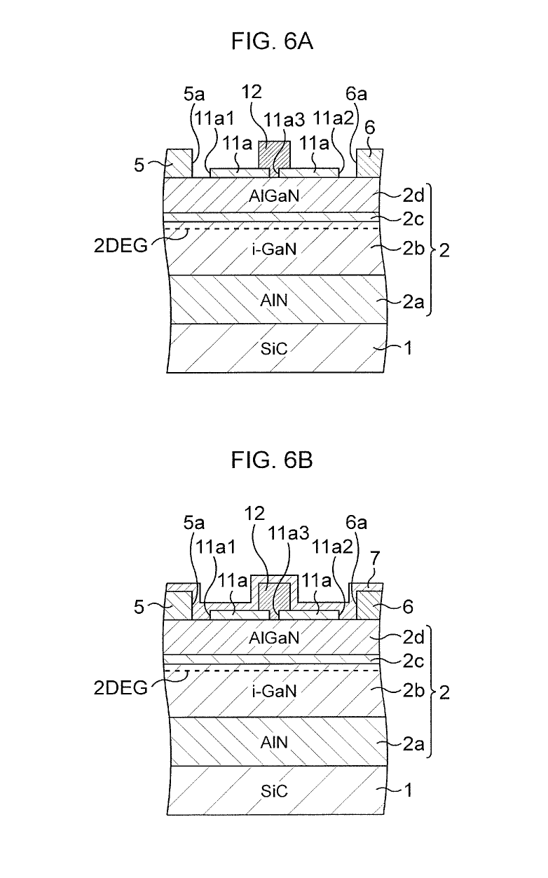

FIG. 5A to FIG. 5C and FIG. 6A and FIG. 6B are schematic cross-sectional views illustrating main processes of a method of manufacturing an AlGaN/GaN.HEMT according to the modified example of the first embodiment.

First, similarly to FIG. 2A and FIG. 2B of the first embodiment, a compound semiconductor stacked structure 2 is formed on a SiC substrate 1. The compound semiconductor stacked structure 2 includes: a buffer layer 2a; an electron transit layer 2b; an intermediate layer 2c; and an electron supply layer 2d.

Subsequently, similarly to the first embodiment, element isolation structures are formed in the compound semiconductor stacked structure 2.

Subsequently, as illustrated in FIG. 5A, an AlN layer 11 is formed.

More specifically, on the compound semiconductor stacked structure 2, an insulating film containing Al, here AlN is deposited to a thickness of 2 nm or so to 200 nm or so, for example, 20 nm or so. For the deposition of AlN, for example, an ALD method is used. Instead of the ALD method, a sputtering method, a plasma CVD method, or the like may also be used. Thereby, the AlN layer 11 is formed. As an insulating material containing Al, for example, AlO(Al₂O₃) may also be used instead of AlN.

Subsequently, as illustrated in FIG. 5B, the AlN layer 11 is processed to form a passivation film 11a.

More specifically, a resist is applied on the surface of the AlN layer 11. The resist is processed by lithography, and thereby openings exposing opening planned sites of the AlN layer 11 are formed in the resist. Thereby, a resist mask having the openings is formed.

By using this resist mask, the AlN layer 11 is dry etched until a predetermined region of the surface of the electron supply layer 2d is exposed. For an etching gas, for example, a chlorine-based gas is used. The predetermined region of the electron supply layer 2d is, of the surface of the electron supply layer 2d, a region including source electrode and drain electrode formation planned sites and a gate electrode formation planned site. Incidentally, the dry etching may also be performed in such a manner to slightly shave the AlN layer 11 in a depth direction beyond the surface of the electron supply layer 2d. Thereby, of the residual AlN layer 11, the passivation film 11a exposing the predetermined region of the electron supply layer 2d is formed. Of the passivation film 11a, both end portions formed by the dry etching are set to end portions 11a1 and 11a2, and the gate electrode formation planned site is set to an electrode recess 11a3.

Subsequently, as illustrated in FIG. 5C, a gate electrode 12 is formed.

More specifically, first, a resist mask for forming the gate electrode is formed. Here, for example, an eaves-structure two-layer resist suitable for a vapor deposition method and a liftoff method is used. This resist is applied on the compound semiconductor stacked structure 2 including the surface of the passivation film 11a and an opening exposing a region including the electrode recess 11a3 of the passivation film 11a is formed. Thereby, the resist mask having the opening is formed.

By using this resist mask, as an electrode material, for example, Ni/Au (Ni for a lower layer and Au for an upper layer) are deposited on the resist mask including the inside of the opening exposing the region including the electrode recess 11a3 of the passivation film 11a by the vapor deposition method, for example. The thickness of Ni is set to 30 nm or so and the thickness of Au is set to 400 nm or so. By the liftoff method, the resist mask and Ni/Au deposited thereon are removed. Thereby, the gate electrode 12 in a shape filling the electrode recess 11a3 and riding on the passivation film 11a (what is called an overhang shape in cross section along a gate length direction) is formed. The gate electrode 12 comes into Schottky contact with the compound semiconductor stacked structure 2 (electron supply layer 2d) in the electrode recess 11a3.

Thereafter, the resist mask is removed by ashing using oxygen plasma or wetting using a chemical solution.

Subsequently, as illustrated in FIG. 6A, a source electrode 5 and a drain electrode 6 are formed.

More specifically, first, a resist mask for forming the source electrode and the drain electrode is formed. Here, for example, an eaves-structure two-layer resist suitable for a vapor deposition method and a liftoff method is used. This resist is applied on the compound semiconductor stacked structure 2 and openings exposing source electrode and drain electrode formation planned sites of the compound semiconductor stacked structure 2 are formed. Thereby, the resist mask having the openings is formed.

By using this resist mask, as an electrode material, for example, Ti/Al (Ti for a lower layer and Al for an upper layer) are deposited on the resist mask including the inside of the openings exposing the respective formation planned sites by the vapor deposition method, for example. The thickness of Ti is set to 20 nm or so and the thickness of Al is set to 200 nm or so. By the liftoff method, the resist mask and Ti/Al deposited thereon are removed. Thereafter, the SiC substrate 1 is subjected to annealing at a temperature of 400° C. to 1000° C. or so, for example, 550° C. or so in a nitrogen atmosphere, for example, and thereby residual Ti/Al are brought into ohmic contact with the electron supply layer 2d. Thereby, the source electrode 5 and the drain electrode 6 are formed on the compound semiconductor stacked structure 2.

In this example, the passivation film 11a is in a non-contact state with the compound semiconductor stacked structure 2 (electron supply layer 2d) under the source electrode 5 and the drain electrode 6. Concretely, between the source electrode 5 and the drain electrode 12, an end portion 5a of the source electrode 5 is separated from the end portion 11a1 of the passivation film 11a. Similarly, between the drain electrode 6 and the gate electrode 12, an end portion 6a of the drain electrode 6 is separated from the end portion 11a2 of the passivation film 11a.

Since being in a separated non-contact state with the source electrode 5 and the drain electrode 6, the passivation film 11a does not react with the source electrode 5 and the drain electrode 6 at the time of the high-temperature annealing for establishing the ohmic contact of the source electrode 5 and the drain electrode 6. Consequently, distribution of contact resistance, of the passivation film 11a, in a gate width direction becomes uniform and current concentration at the time of high-voltage operation is dispersed, resulting in that a sufficient breakdown withstand voltage can be obtained.

Subsequently, as illustrated in FIG. 6B, a protective insulating film 7 is formed on the whole surface.

More specifically, an insulating film, for example, SiN is deposited to cover the whole surface on the compound semiconductor stacked structure 2 to a thickness of 2 nm or so to 200 nm or so, for example, 20 nm or so, and for the deposition of SiN, a plasma CVD method or a sputtering method is used. As an insulating material, there is sometimes a case that SiON, SiO₂, or the like is used instead of SiN. Thereby, the protective insulating film 7 is formed. The protective insulating film 7 fills a gap between the source electrode 5 and the passivation film 11a and a gap between the drain electrode 6 and the passivation film 11a to function as a protective film.

Thereafter, various processes such as forming an interlayer insulating film, forming wirings connected to the gate electrode 12, the source electrode 5, and the drain electrode 6, forming an upper protective film, and forming a connection electrode exposed on the uppermost surface are undergone. Thereby, the Schottky-type AlGaN/GaN.HEMT according to this embodiment is formed.

As explained above, in this example, the highly reliable high-withstand-voltage AlGaN/GaN.HEMT that reduces the current collapse phenomenon by using the passivation film 11a containing Al and further secures the sufficient breakdown withstand voltage is achieved.

(Second Embodiment)

This embodiment discloses a structure of a MIS-type AlGaN/GaN.HEMT and a method of manufacturing the same as in the first embodiment, but is different from the first embodiment in that the formation state of the passivation film is slightly different. Note that the same constituent members and so on as those in the first embodiment will be denoted by the same reference signs, and a detailed explanation thereof will be omitted.

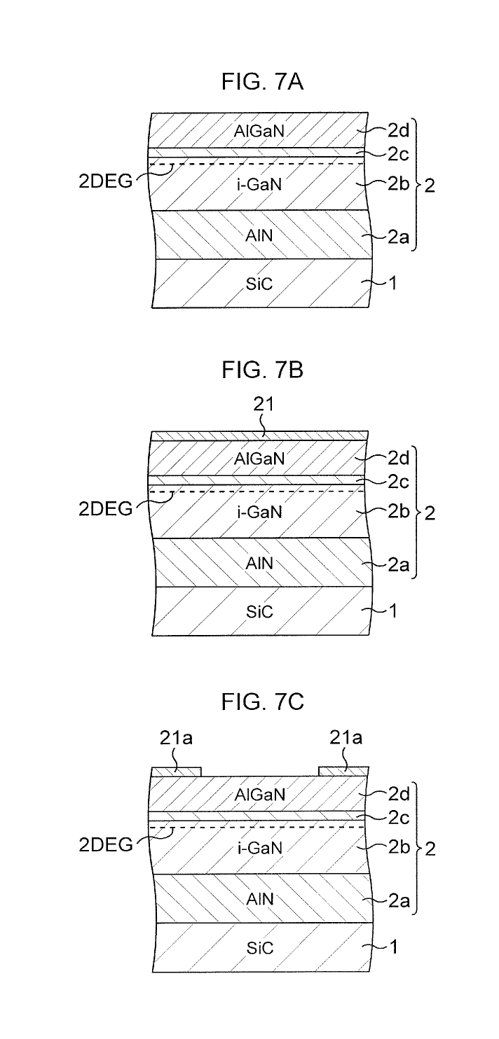

FIG. 7A to FIG. 7C to FIG. 9A and FIG. 9B are schematic cross-sectional views illustrating a method of manufacturing an AlGaN/GaN.HEMT according to a second embodiment in order of processes.

First, as illustrated in FIG. 7A, a compound semiconductor stacked structure 2 is formed on, for example, a semi-insulating SiC substrate 1 as a growth substrate. The compound semiconductor stacked structure 2 includes: a buffer layer 2a; an electron transit layer 2b; an intermediate layer 2c; and an electron supply layer 2d. A method of growing the compound semiconductor stacked structure 2 is similar to that of the first embodiment.

Subsequently, similarly to the first embodiment, element isolation structures are formed in the compound semiconductor stacked structure 2.

Subsequently, as illustrated in FIG. 7B, an SiN film 21 is formed on the whole surface.

More specifically, an insulating film, for example, SiN is deposited to cover the whole surface on the compound semiconductor stacked structure 2 to a thickness of 2 nm or so to 200 nm or so, for example, 20 nm or so, and for the deposition of SiN, a plasma CVD method or a sputtering method is used. As an insulating material, there is sometimes a case that SiON, SiO₂, or the like is used instead of SiN. Thereby, the SiN film 21 is formed.

Subsequently, as illustrated in FIG. 7C, the SiN film 21 is processed.

More specifically, a resist is applied on the surface of the SiN film 21. The resist is processed by lithography, and thereby an opening exposing an opening planned site of the SiN film 21 is formed in the resist. Thereby, a resist mask having the opening is formed.

By using this resist mask, the SiN film 21 is dry etched until a predetermined region of the surface of the electron supply layer 2d is exposed. For an etching gas, for example, a fluorine-based gas is used. In this dry etching, an etching damage to be given to the electron supply layer 2d needs to be as small as possible, and the dry etching using the fluorine-based gas gives a small etching damage to the electron supply layer 2d. The predetermined region of the electron supply layer 2d is a region between a source electrode formation planned site and a drain electrode formation planned site of the surface of the electron supply layer 2d. The SiN film 21 made residual by the dry etching is set to an SiN film 21a.

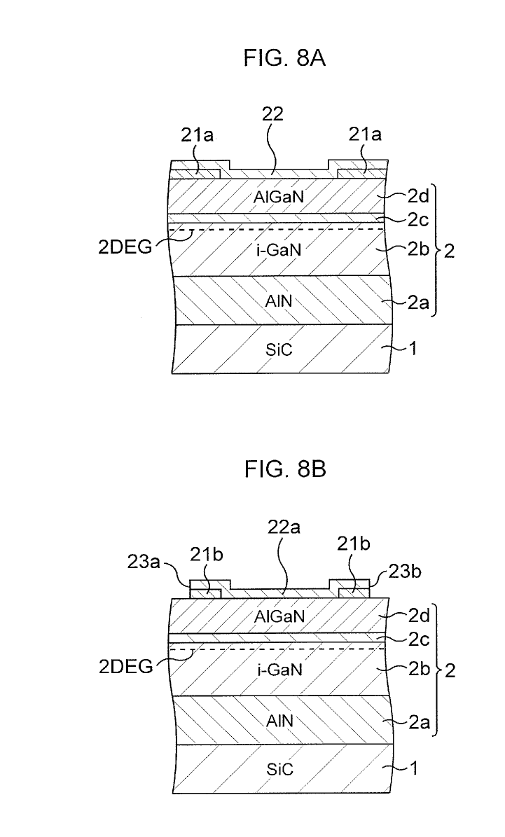

Subsequently, as illustrated in FIG. 8A, an AlN layer 22 is formed.

More specifically, on the compound semiconductor stacked structure 2 including the surface of the SiN film 21a, an insulating film containing Al, here AlN is deposited to a thickness of 2 nm or so to 200 nm or so, for example, 20 nm or so. For the deposition of AlN, for example, an ALD method is used. Instead of the ALD method, a sputtering method, a plasma CVD method, or the like may also be used. Thereby, the AlN layer 22 is formed. As an insulating material containing Al, for example, AlO (Al₂O₃) may also be used instead of AlN.

Subsequently, as illustrated in FIG. 8B, the SiN film 21a is processed together with the AlN layer 22 to form a passivation film 22a and a foundation layer 21b.

More specifically, a resist is applied on the surface of the AlN layer 22. The resist is processed by lithography, and thereby openings exposing opening planned sites of the AlN layer 22 are formed in the resist. Thereby, a resist mask having the openings is formed.

By using this resist mask, the AlN layer 22 and the SiN film 21a are dry etched until the predetermined region of the surface of the electron supply layer 2d is exposed. As an etching gas, for example, a chlorine-based gas is used for the etching of the AlN layer 22, and, for example, a fluorine-based gas is used for the etching of the SiN film 21a. Even if the AlN layer 22 is dry etched by using a chlorine-based gas, the electron supply layer 2d is not exposed to the dry etching and there is no etching damage given to the electron supply layer 2d because the SiN film 21a exists on the electron supply layer 2d. The SiN film 21a on the electron supply layer 2d is dry etched by using a fluorine-based gas, and thereby an etching damage given to the electron supply layer 2d exposed by the dry etching of the SiN film 21a can be suppressed small.

The predetermined region of the electron supply layer 2d is, of the source electrode and drain electrode formation planned sites of the surface of the electron supply layer 2d, a region where the source electrode and the drain electrode come into ohmic contact with the electron supply layer 2d. Thereby, of the residual AlN layer 22, the passivation film 22a exposing the predetermined region of the electron supply layer 2d is formed. Under the passivation film 22a, the foundation layer 21b is formed of the residual SiN film 21a. In the foundation layer 21b and the passivation film 22a, the above-described predetermined region exposed by the dry etching is set to electrode recesses 23a and 23b.

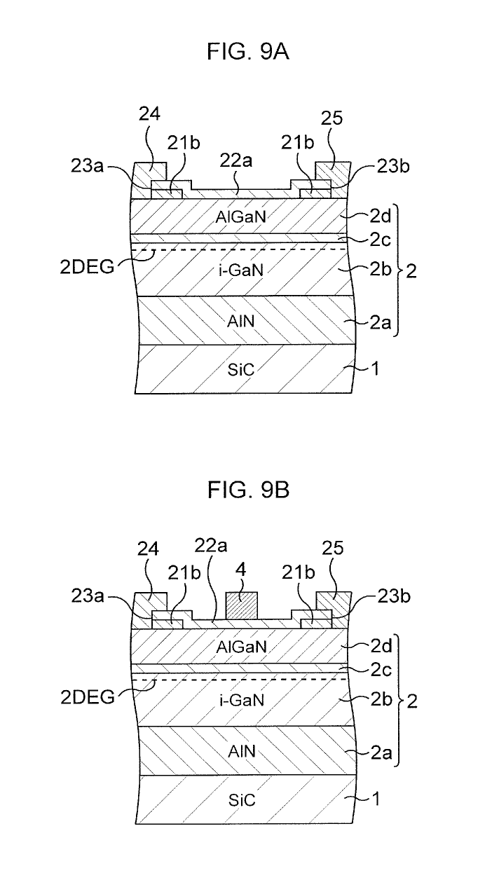

Subsequently, as illustrated in FIG. 9A, a source electrode 24 and a drain electrode 25 are formed.

More specifically, first, a resist mask for forming the source electrode and the drain electrode is formed. Here, for example, an eaves-structure two-layer resist suitable for a vapor deposition method and a liftoff method is used. This resist is applied on the compound semiconductor stacked structure 2 and openings exposing the source electrode and drain electrode formation planned sites including the electrode recesses 23a and 23b are formed. Thereby, the resist mask having the openings is formed.

By using this resist mask, as an electrode material, for example, Ti/Al (Ti for a lower layer and Al for an upper layer) are deposited on the resist mask including the inside of the openings exposing the respective formation planned sites by the vapor deposition method, for example. The thickness of Ti is set to 20 nm or so and the thickness of Al is set to 200 nm or so. By the liftoff method, the resist mask and Ti/Al deposited thereon are removed. Thereafter, the SiC substrate 1 is subjected to annealing at a temperature of 400° C. to 1000° C. or so, for example, 550° C. or so in a nitrogen atmosphere, for example, and thereby residual Ti/Al are brought into ohmic contact with the electron supply layer 2d in the electrode recesses 23a and 23b. Thereby, the source electrode 24 in a shape filling the electrode recess 23a and riding on the passivation film 22a (what is called an overhang shape in cross section along a gate length direction), and the drain electrode 25 in a shape filling the electrode recess 23b and riding on the passivation film 22a (what is called an overhang shape in cross section along the gate length direction) are formed.

In this embodiment, the passivation film 22a is in a non-contact state with the compound semiconductor stacked structure 2 (electron supply layer 2d) under the source electrode 24 and the drain electrode 25. Concretely, the passivation film 22a is positioned above the electron supply layer 2d via the foundation layer 21b in lower portions of the source electrode 24 and the drain electrode 25.

The passivation film 22a comes into contact with the source electrode 24 and the drain electrode 25 in the lower portions of the source electrode 24 and the drain electrode 25, but is separated above from the electron supply layer 2d via the foundation layer 21b. That is, the portion where three of the electron supply layer 2d, Ti of the source electrode 24 and the drain electrode 25, and the passivation film 22a come into contact with one another simultaneously does not exist. In this case, at the time of the high-temperature annealing for establishing the ohmic contact of the source electrode 24 and the drain electrode 25, the passivation film 22a does not react with the source electrode 24 and the drain electrode 25. Consequently, distribution of contact resistance, of the passivation film 22a, in a gate width direction becomes uniform and current concentration at the time of high-voltage operation is dispersed, resulting in that a sufficient breakdown withstand voltage can be obtained.

Subsequently, as illustrated in FIG. 9B, a gate electrode 4 is formed.

More specifically, first, a resist mask for forming the gate electrode is formed. Here, for example, an eaves-structure two-layer resist suitable for a vapor deposition method and a liftoff method is used. This resist is applied on the passivation film 22a and an opening exposing a gate electrode formation planned site of the passivation film 22a is formed. Thereby, the resist mask having the opening is formed.

By using this resist mask, as an electrode material, for example, Ni/Au (Ni for a lower layer and Au for an upper layer) are deposited on the resist mask including the inside of the opening exposing the gate electrode formation planned site of the passivation film 22a by the vapor deposition method, for example. The thickness of Ni is set to 30 nm or so and the thickness of Au is set to 400 nm or so. By the liftoff method, the resist mask and Ni/Au deposited thereon are removed. Thereby, the gate electrode 4 is formed on the passivation film 22a. The gate electrode 4 is formed on the compound semiconductor stacked structure 2 via the passivation film 22a. The portion, of the passivation film 22a, positioned under the gate electrode 4 functions as a gate insulating film.

Thereafter, the resist mask is removed by ashing using oxygen plasma or wetting using a chemical solution.

Thereafter, various processes such as forming an interlayer insulating film, forming wirings connected to the gate electrode 4, the source electrode 24, and the drain electrode 25, forming an upper protective film, and forming a connection electrode exposed on the uppermost surface are undergone. Thereby, the MIS-type AlGaN/GaN.HEMT according to this embodiment is formed.

As explained above, in this embodiment, the highly reliable high-withstand-voltage AlGaN/GaN.HEMT that reduces the current collapse phenomenon by using the passivation film 22a containing Al and further secures the sufficient breakdown withstand voltage is achieved.

(Modified Example)

Hereinafter, there will be explained a modified example of the second embodiment. In this example, a structure of an AlGaN/GaN.HEMT and a method of manufacturing the same are disclosed as in the second embodiment, but what is called a Schottky-type AlGaN/GaN.HEMT in which a gate electrode comes into Schottky contact with a semiconductor is illustrated as an example. Note that the same constituent members and so on as those of the second embodiment will be denoted by the same reference signs, and a detailed explanation thereof will be omitted.

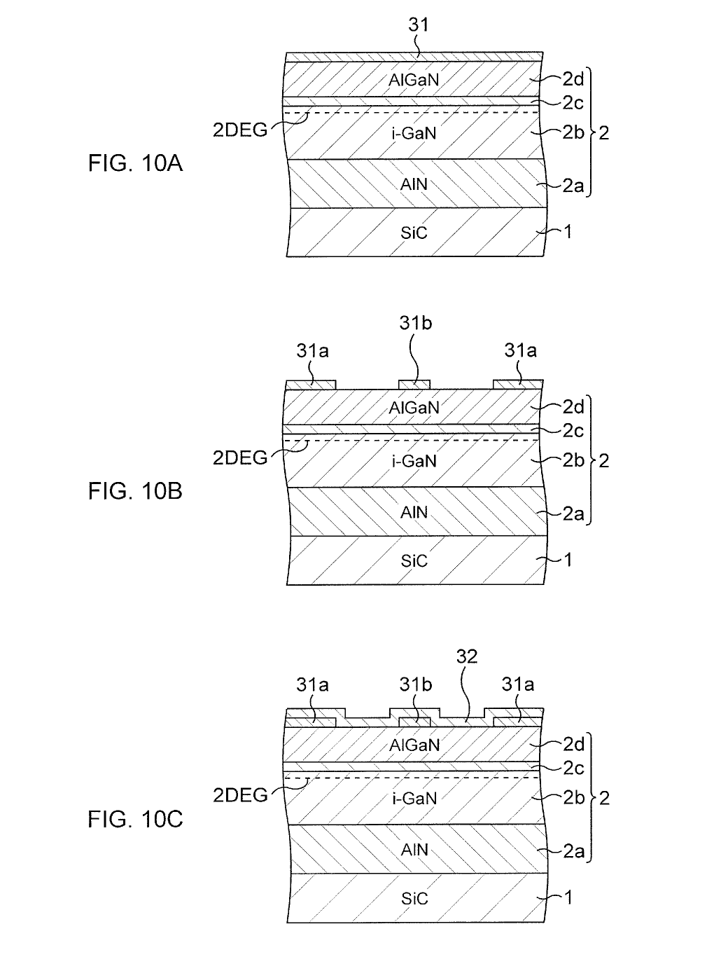

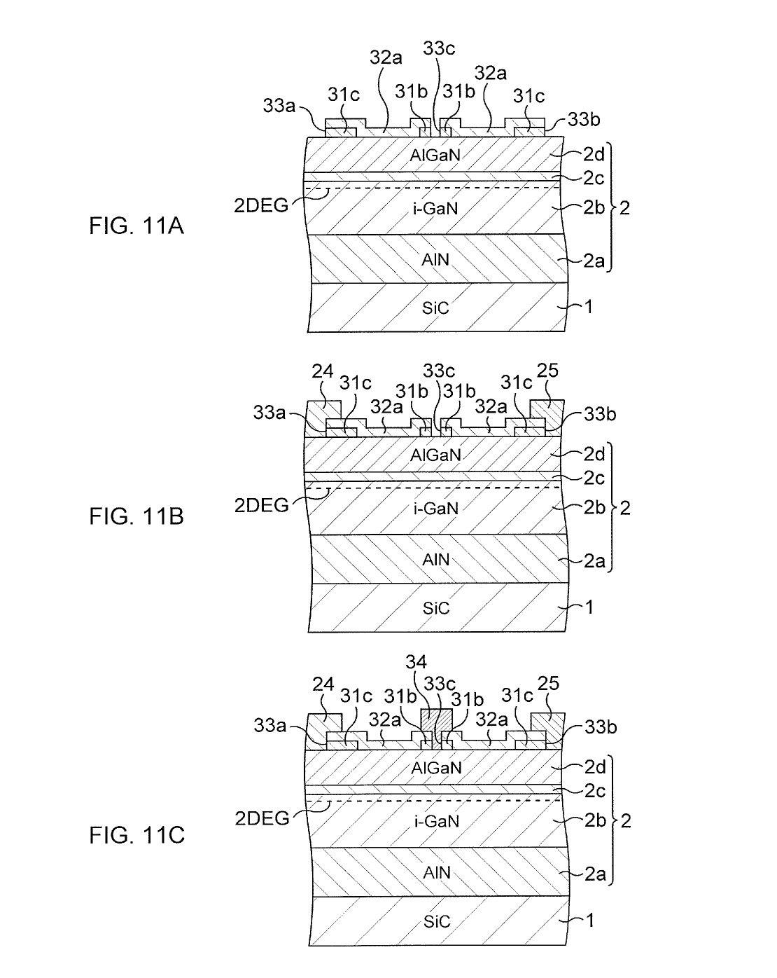

FIG. 10A to FIG. 10C and FIG. 11A to FIG. 11C are schematic cross-sectional views illustrating main processes of a method of manufacturing an AlGaN/GaN.HEMT according to the modified example of the second embodiment.

First, similarly to FIG. 2A and FIG. 2B of the first embodiment, a compound semiconductor stacked structure 2 is formed on a SiC substrate 1. The compound semiconductor stacked structure 2 includes: a buffer layer 2a; an electron transit layer 2b; an intermediate layer 2c; and an electron supply layer 2d.

Subsequently, similarly to the first embodiment, element isolation structures are formed in the compound semiconductor stacked structure 2.

Subsequently, as illustrated in FIG. 10A, an SiN film 31 is formed on the whole surface.

More specifically, an insulating film, for example, SiN is deposited to cover the whole surface on the compound semiconductor stacked structure 2 to a thickness of 2 nm or so to 200 nm or so, for example, 20 nm or so, and for the deposition of SiN, a plasma CVD method or a sputtering method is used. As an insulating material, there is sometimes a case that SiON, SiO₂, or the like is used instead of SiN. Thereby, the SiN film 31 is formed.

Subsequently, as illustrated in FIG. 10B, the SiN film 31 is processed.

More specifically, a resist is applied on the surface of the SiN film 31. The resist is processed by lithography, and thereby openings exposing opening planned sites of the SiN film 31 are formed in the resist. Thereby, a resist mask having the openings is formed.

By using this resist mask, the SiN film 31 is dry etched until a predetermined region of the surface of the electron supply layer 2d is exposed. For an etching gas, for example, a fluorine-based gas is used. In this dry etching, an etching damage to be given to the electron supply layer 2d needs to be as small as possible, and the dry etching using the fluorine-based gas gives a small etching damage to the electron supply layer 2d. The predetermined region of the electron supply layer 2d is a region excluding respective source electrode, drain electrode, and gate electrode formation planned sites of the surface of the electron supply layer 2d. Thereby, the residual SiN film 31 is set to SiN films 31a and 31b.

Subsequently, as illustrated in FIG. 10C, an AlN layer 32 is formed.

More specifically, on the compound semiconductor stacked structure 2 including the surfaces of the SiN films 31a and 31b, an insulating film containing Al, here AlN is deposited to a thickness of 2 nm or so to 200 nm or so, for example, 20 nm or so. For the deposition of AlN, for example, an ALD method is used. Instead of the ALD method, a sputtering method, a plasma CVD method, or the like may also be used. Thereby, the AlN layer 32 is formed. As an insulating material containing Al, for example, AlO (Al₂O₃) may also be used instead of AlN.

Subsequently, as illustrated in FIG. 11A, a passivation films 32a and a foundation layer 31c are formed.

More specifically, a resist is applied on the surface of the AlN layer 32. The resist is processed by lithography, and thereby openings exposing opening planned sites of the AlN layer 32 are formed in the resist. Thereby, a resist mask having the openings is formed.

By using this resist mask, the AlN layer 32 and the SiN films 31a and 31b are dry etched until the predetermined region of the surface of the electron supply layer 2d is exposed. As an etching gas, for example, a chlorine-based gas is used for the etching of the AlN layer 32, and, for example, a fluorine-based gas is used for the etching of the SiN films 31a and 31b. Even if the AlN layer 32 is dry etched by using a chlorine-based gas, the electron supply layer 2d is not exposed to the dry etching and there is no etching damage given to the electron supply layer 2d because the SiN films 31a and 31b exist on the electron supply layer 2d. The SiN films 31a and 31b on the electron supply layer 2d are dry etched by using a fluorine-based gas, and thereby an etching damage given to the electron supply layer 2d exposed by the dry etching of the SiN films 31a and 31b can be suppressed small.

The predetermined region of the electron supply layer 2d is, of the source electrode and drain electrode formation planned sites of the surface of the electron supply layer 2d, a region where the source electrode and the drain electrode come into ohmic contact with the electron supply layer 2d, and is, of the gate electrode formation planned site, a region where the gate electrode comes into Schottky contact with the electron supply layer 2d. Thereby, of the residual AlN layer 32, the passivation film 32a exposing the predetermined region of the electron supply layer 2d is formed. Under the passivation film 32a on the source electrode and drain electrode formation planned site sides, the foundation layer 31c is formed of the residual SiN film 31a. Under the passivation film 32a on the gate electrode formation planned site side, the SiN film 31b remains. In the foundation layer 31c and the passivation film 32a, the above-described predetermined region exposed by the dry etching is set to electrode recesses 33a and 33b of the source electrode and the drain electrode. In the residual SiN film 31a and the passivation film 32a, the above-described predetermined region exposed by the dry etching is set to an electrode recess 33b of the gate electrode.

Subsequently, as illustrated in FIG. 11B, a source electrode 24 and a drain electrode 25 are formed.

More specifically, first, a resist mask for forming the source electrode and the drain electrode is formed. Here, for example, an eaves-structure two-layer resist suitable for a vapor deposition method and a liftoff method is used. This resist is applied on the compound semiconductor stacked structure 2 and openings exposing the source electrode and drain electrode formation planned sites including the electrode recesses 33a and 33b are formed. Thereby, the resist mask having the openings is formed.

By using this resist mask, as an electrode material, for example, Ti/Al (Ti for a lower layer and Al for an upper layer) are deposited on the resist mask including the inside of the openings exposing the respective formation planned sites by the vapor deposition method, for example. The thickness of Ti is set to 20 nm or so and the thickness of Al is set to 200 nm or so. By the liftoff method, the resist mask and Ti/Al deposited thereon are removed. Thereafter, the SiC substrate 1 is subjected to annealing at a temperature of 400° C. to 1000° C. or so, for example, 550° C. or so in a nitrogen atmosphere, for example, and thereby residual Ti/Al are brought into ohmic contact with the electron supply layer 2d in the electrode recesses 33a and 33b. Thereby, the source electrode 24 in a shape filling the electrode recess 33a and riding on the passivation film 32a (what is called an overhang shape in cross section along a gate length direction), and the drain electrode 25 in a shape filling the electrode recess 33b and riding on the passivation film 32a (what is called an overhang shape in cross section along the gate length direction) are formed.

In this example, the passivation film 32a is in a non-contact state with the compound semiconductor stacked structure 2 (electron supply layer 2d) under the source electrode 24 and the drain electrode 25. Concretely, the passivation film 32a is positioned above the electron supply layer 2d via the foundation layer 31c in lower portions of the source electrode 24 and the drain electrode 25.

The passivation film 32a comes into contact with the source electrode 24 and the drain electrode 25 in the lower portions of the source electrode 24 and the drain electrode 25, but is separated above from the electron supply layer 2d via the foundation layer 31c. That is, the portion where three of the electron supply layer 2d, Ti of the source electrode 24 and the drain electrode 25, and the passivation film 32a come into contact with one another simultaneously does not exist. In this case, at the time of the high-temperature annealing for establishing the ohmic contact of the source electrode 24 and the drain electrode 25, the passivation film 32a does not react with the source electrode 24 and the drain electrode 25. Consequently, distribution of contact resistance, of the passivation film 32a, in a gate width direction becomes uniform and current concentration at the time of high-voltage operation is dispersed, resulting in that a sufficient breakdown withstand voltage can be obtained.

Subsequently, as illustrated in FIG. 11C, a gate electrode 34 is formed.

More specifically, first, a resist mask for forming the gate electrode is formed. Here, for example, an eaves-structure two-layer resist suitable for a vapor deposition method and a liftoff method is used. This resist is applied on the passivation film 32a and an opening exposing a region including the electrode recess 33c of the passivation film 32a is formed. Thereby, the resist mask having the opening is formed.

By using this resist mask, as an electrode material, for example, Ni/Au (Ni for a lower layer and Au for an upper layer) are deposited on the resist mask including the inside of the opening by the vapor deposition method, for example. The thickness of Ni is set to 30 nm or so and the thickness of Au is set to 400 nm or so. By the liftoff method, the resist mask and Ni/Au deposited thereon are removed. Thereby, the gate electrode 34 in a shape filling the electrode recess 33c and riding on the passivation film 32a (what is called an overhang shape in cross section along the gate length direction) is formed. The gate electrode 34 comes into Schottky contact with the compound semiconductor stacked structure 2 (electron supply layer 2d) in the electrode recess 33c.

Thereafter, the resist mask is removed by ashing using oxygen plasma or wetting using a chemical solution.

Thereafter, various processes such as forming an interlayer insulating film, forming wirings connected to the gate electrode 34, the source electrode 24, and the drain electrode 25, forming an upper protective film, and forming a connection electrode exposed on the uppermost surface are undergone. Thereby, the Schottky-type AlGaN/GaN.HEMT according to this embodiment is formed.

As explained above, in this embodiment, the highly reliable high-withstand-voltage AlGaN/GaN.HEMT that reduces the current collapse phenomenon by using the passivation film 32a containing Al and further secures the sufficient breakdown withstand voltage is achieved.

(Third Embodiment)

In this embodiment, there is disclosed a power supply device to which one type selected from the AlGaN/GaN.HEMTs according to the first and second embodiments and their modified examples is applied.

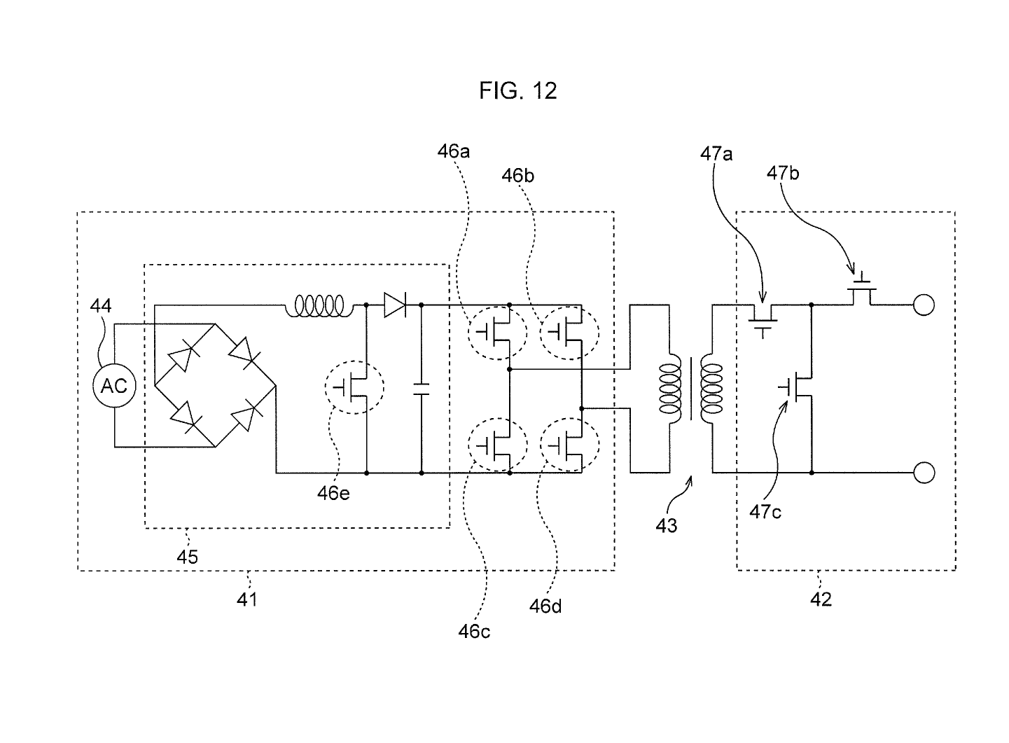

FIG. 12 is a connection diagram illustrating a schematic configuration of a power supply device according to a third embodiment.

The power supply device according to this embodiment includes: a high-voltage primary-side circuit 41; a low-voltage secondary-side circuit 42; and a transformer 43 disposed between the primary-side circuit 41 and the secondary-side circuit 42.

The primary-side circuit 41 includes: an AC power supply 44; what is called a bridge rectifying circuit 45; and a plurality of (four here) switching elements 46a, 46b, 46c, and 46d. Further, the bridge rectifying circuit 45 has a switching element 46e.

The secondary-side circuit 42 includes a plurality of (three here) switching elements 47a, 47b, and 47c.

In this embodiment, the switching elements 46a, 46b, 46c, 46d, and 46e of the primary-side circuit 41 each are one type selected from the AlGaN/GaN.HEMTs according to the first and second embodiments and their modified examples. On the other hand, the switching elements 47a, 47b, and 47c of the secondary-side circuit 42 each are an ordinary MIS.FET using silicon.

In this embodiment, the highly reliable high-withstand-voltage AlGaN/GaN.HEMT that reduces the current collapse phenomenon by using the passivation film containing Al and further secures the sufficient breakdown withstand voltage is applied to the power supply device. Thereby, a highly reliable large-power power supply device is achieved.

(Fourth Embodiment)

In this embodiment, there is disclosed a high-frequency amplifier to which one type selected from the AlGaN/GaN.HEMTs according to the first and second embodiments and their modified examples is applied.

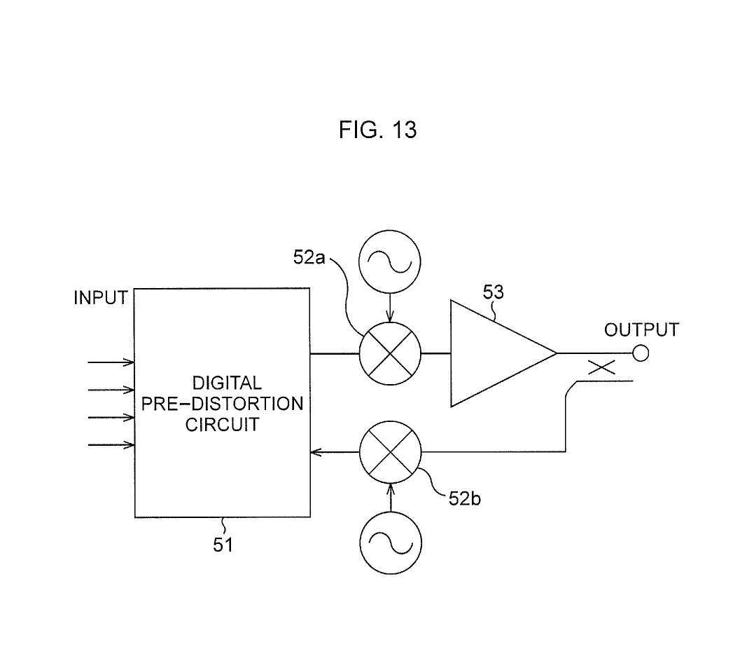

FIG. 13 is a connection diagram illustrating a schematic configuration of a high-frequency amplifier according to a fourth embodiment.

The high-frequency amplifier according to this embodiment includes: a digital.pre-distortion circuit 51; mixers 52a and 52b; and a power amplifier 53.

The digital.pre-distortion circuit 51 compensates nonlinear distortion of an input signal. The mixer 52a mixes the input signal whose nonlinear distortion is compensated and an AC signal. The power amplifier 53 amplifies the input signal mixed with the AC signal, and has one type selected from the AlGaN/GaN.HEMTs according to the first and second embodiments and their modified examples. Incidentally, in FIG. 13, by, for example, changing the switches, an output-side signal can be mixed with the AC signal by the mixer 52b, and the resultant can be sent out to the digital.pre-distortion circuit 51.

In this embodiment, the highly reliable high-withstand-voltage AlGaN/GaN.HEMT that reduces the current collapse phenomenon by using the passivation film containing Al and further secures the sufficient breakdown withstand voltage is applied to the high-frequency amplifier. Thereby, a highly reliable high-withstand-voltage high-frequency amplifier is achieved.

(Other Embodiments)

In the first to fourth embodiments and various modified examples, the AlGaN/GaN.HEMTs are exemplified as the compound semiconductor devices. Other than the AlGaN/GaN.HEMTs, the following HEMTs are applicable as the compound semiconductor devices.

Other HEMT Example 1

In this example, an InAlN/GaN.HEMT is disclosed as the compound semiconductor device.

InAlN and GaN are compound semiconductors whose lattice constants can be made close to each other by their compositions. In this case, in the above-described first to fourth embodiments and various modified examples, the electron transit layer is formed of i-GaN, the intermediate layer is formed of i-InAlN, and the electron supply layer is formed of i-InAlN. Further, in this case, piezoelectric polarization barely occurs, and thus the two-dimensional electron gas mainly occurs by spontaneous polarization of InAlN.

According to this example, similarly to the above-described AlGaN/GaN.HEMTs, a highly reliable high-withstand-voltage InAlN/GaN.HEMT that reduces a current collapse phenomenon by using a passivation film containing Al and further secures a sufficient breakdown withstand voltage is achieved.

Other HEMT Example 2

In this example, an InAlGaN/GaN.HEMT is disclosed as the compound semiconductor device.

GaN and InAlGaN are compound semiconductors that the lattice constant of the latter can be made smaller than the lattice constant of the former by their compositions. In this case, in the above-described first to fourth embodiments and various modified examples, the electron transit layer is formed of i-GaN, the intermediate layer is formed of i-InAlGaN, and the electron supply layer is formed of n-InAlGaN.

According to this example, similarly to the above-described AlGaN/GaN.HEMTs, a highly reliable high-withstand-voltage InAlGaN/GaN.HEMT that reduces a current collapse phenomenon by using a passivation film containing Al and further secures a sufficient breakdown withstand voltage is achieved.

According to the above-described various aspects, a highly reliable high-withstand-voltage compound semiconductor device that reduces a current collapse phenomenon by using a protective film containing Al and further secures a sufficient breakdown withstand voltage is achieved.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A compound semiconductor device comprising:
a compound semiconductor stacked structure;
a pair of first electrodes that are formed separately from each other above the compound semiconductor stacked structure;
a second electrode that is formed between the first electrodes above the compound semiconductor stacked structure; and
a protective film that is formed above the compound semiconductor stacked structure and made of an insulating material containing aluminum, wherein
the protective film is in a non-contact state with the compound semiconductor stacked structure under the first electrodes.

2. The compound semiconductor device according to claim 1, further comprising:
a foundation layer that is formed under the first electrodes, wherein
the protective film is positioned above the compound semiconductor stacked structure via the foundation layer under the first electrodes.

3. The compound semiconductor device according to claim 1, wherein
the protective film is formed separately from the first electrode between the first electrode and the second electrode.

4. The compound semiconductor device according to claim 1, wherein
the protective film is formed of AlN or AlO as a material.

5. The compound semiconductor device according to claim 1, wherein
the second electrode is formed above the compound semiconductor stacked structure via the protective film.

6. The compound semiconductor device according to claim 1, wherein
the second electrode comes into contact with the compound semiconductor stacked structure through an opening formed in the protective film.

7. A method of manufacturing a compound semiconductor device comprising:
forming a compound semiconductor stacked structure;
forming a protective film made of an insulating material containing aluminum above the compound semiconductor stacked structure;
forming a pair of first electrodes separated from each other above the compound semiconductor stacked structure; and
forming a second electrode between the first electrodes above the compound semiconductor stacked structure, wherein
the protective film is in a non-contact state with the compound semiconductor stacked structure under the first electrodes.

8. The method of manufacturing the compound semiconductor device according to claim 7, further comprising:
forming a foundation layer under the first electrodes, wherein
the protective film is positioned above the compound semiconductor stacked structure via the foundation layer under the first electrodes.

9. The method of manufacturing the compound semiconductor device according to claim 7, wherein
the protective film is formed separately from the first electrode between the first electrode and the second electrode.

10. The method of manufacturing the compound semiconductor device according to claim 7, wherein
the protective film is formed of AlN or AlO as a material.

11. The method of manufacturing the compound semiconductor device according to claim 7, wherein
the second electrode is formed above the compound semiconductor stacked structure via the protective film.

12. The method of manufacturing the compound semiconductor device according to claim 7, wherein
the second electrode comes into contact with the compound semiconductor stacked structure through an opening formed in the protective film.

13. A power supply circuit comprising:
a transformer; and
a high-voltage circuit and a low-voltage circuit sandwiching the transformer, the high-voltage circuit comprising:
a transistor, the transistor comprising:
a compound semiconductor stacked structure;
a pair of first electrodes that are formed separately from each other above the compound semiconductor stacked structure;
a second electrode that is formed between the first electrodes above the compound semiconductor stacked structure; and
a protective film that is formed above the compound semiconductor stacked structure and made of an insulating material containing aluminum, wherein
the protective film is in a non-contact state with the compound semiconductor stacked structure under the first electrodes.
